(19) United States
(12) Patent Application Publication
(10) Pub. No.: US 2023/0378219 A1
(43) Pub. Date: Nov. 23, 2023

(54) IMAGING DEVICE AND ELECTRONIC APPARATUS

(71) Applicant: SONY SEMICONDUCTOR SOLUTIONS CORPORATION, Kanagawa (JP)

(72) Inventor: Takashi YOKOYAMA, Kanagawa (JP)

(73) Assignee: SONY SEMICONDUCTOR SOLUTIONS CORPORATION, Kanagawa (JP)

(21) Appl. No.: 18/248,268

(22) PCT Filed: Sep. 27, 2021
(86) PCT No.: PCT/JP2021/035336

§ 371 Date: Apr. 7, 2023

(30) Foreign Application Priority Data
Oct. 16, 2020 (JP) 2020-174497

(51) Int. Cl. H01L 27/146; H01L 23/00

(52) U.S. Cl. CPC H01L 27/14634; H01L 27/14616; H01L 24/08; H01L 24/80; H01L 27/1469; H01L 2224/08145; H01L 2224/80006; H01L 2224/80895; H01L 2224/80896

(57) ABSTRACT

An imaging device according to an embodiment of the present disclosure includes: a first substrate; and a second substrate. The first substrate includes one or more sensor pixels that each perform photoelectric conversion. The second substrate is stacked on the first substrate and electrically coupled to the first substrate. The second substrate includes a transistor that operates in a full depletion mode.

### TECHNICAL FIELD

The present disclosure relates to an imaging device having a three-dimensional structure and an electronic apparatus including the imaging device.

### BACKGROUND ART

For example, PTL 1 discloses an imaging device in which a wafer provided with a plurality of solid-state imaging elements and a wafer provided with a memory circuit, a logic circuit, and the like are stacked.

### CITATION LIST

### Patent Literature

PTL 1: International Publication No. WO 2019/087764

### SUMMARY OF THE INVENTION

Incidentally, an imaging device is requested to be miniaturized.

It is desirable to provide an imaging device and an electronic apparatus that each make it possible to achieve miniaturization.

An imaging device according to an embodiment of the present disclosure includes: a first substrate; and a second substrate. The first substrate includes one or more sensor pixels that each perform photoelectric conversion. The second substrate is stacked on the first substrate and electrically coupled to the first substrate. The second substrate includes a transistor that operates in a full depletion mode.

An electronic apparatus according to an embodiment of the present disclosure includes the imaging device according to the embodiment of the present disclosure described above.

In the imaging device according to the embodiment of the present disclosure and the electronic apparatus according to the embodiment, the transistor that operates in the full depletion mode is used as a transistor provided in the second substrate stacked on the first substrate including the one or more sensor pixels. This reduces a thickness of the second substrate.

### BRIEF DESCRIPTION OF DRAWING

FIG. 1 is a cross-sectional schematic diagram illustrating a configuration of an imaging device according to a first embodiment of the present disclosure.

FIG. 2 is an exploded perspective view of a schematic configuration of the imaging device illustrated in FIG. 1.

FIG. 3A is a cross-sectional schematic diagram describing an example of a step of manufacturing the imaging device illustrated in FIG. 1.

FIG. 3B is a cross-sectional schematic diagram illustrating a step subsequent to FIG. 3A.

FIG. 3C is a cross-sectional schematic diagram illustrating a step subsequent to FIG. 3B.

FIG. 3D is a cross-sectional schematic diagram illustrating a step subsequent to FIG. 3C.

FIG. 3E is a cross-sectional schematic diagram illustrating a step subsequent to FIG. 3D.

FIG. 3F is a cross-sectional schematic diagram illustrating a step subsequent to FIG. 3E.

FIG. 3G is a cross-sectional schematic diagram illustrating a step subsequent to FIG. 3F.

FIG. 3H is a cross-sectional schematic diagram illustrating a step subsequent to FIG. 3G.

FIG. 3I is a cross-sectional schematic diagram illustrating a step subsequent to FIG. 3H.

FIG. 3J is a cross-sectional schematic diagram illustrating a step subsequent to FIG. 3I.

FIG. 4 is a cross-sectional schematic diagram illustrating an example of a configuration of an imaging device according to a modification example 1 of the present disclosure.

FIG. 5 is a perspective view of an example of a transistor used for the imaging device according to the modification example 1 of the present disclosure.

FIG. 6 is a cross-sectional schematic diagram illustrating another example of the configuration of the imaging device according to the modification example 1 of the present disclosure.

FIG. 7 is a cross-sectional schematic diagram illustrating an example of a configuration of an imaging device according to a modification example 2 of the present disclosure.

FIG. 8 is a cross-sectional schematic diagram illustrating an example of a configuration of an imaging device according to a modification example 3 of the present disclosure.

FIG. 9A is a cross-sectional schematic diagram describing an example of a step of manufacturing the imaging device illustrated in FIG. 8.

FIG. 9B is a cross-sectional schematic diagram illustrating a step subsequent to FIG. 9A.

FIG. 9C is a cross-sectional schematic diagram illustrating a step subsequent to FIG. 9B.

FIG. 9D is a cross-sectional schematic diagram illustrating a step subsequent to FIG. 9C.

FIG. 9E is a cross-sectional schematic diagram illustrating a step subsequent to FIG. 9D.

FIG. 10 is a cross-sectional schematic diagram illustrating an example of a configuration of an imaging device according to a modification example 4 of the present disclosure.

FIG. 11 is a cross-sectional schematic diagram illustrating another example of the configuration of the imaging device according to the modification example 4 of the present disclosure.

FIG. 12 is an equivalent circuit diagram illustrating an example of a configuration of a NAND circuit.

FIG. 13 is a plane schematic diagram illustrating an example of a wiring layout in a typical imaging device.

FIG. 14 is a plane schematic diagram illustrating an example of a wiring layout in the imaging device illustrated in FIG. 11.

FIG. 15 is a cross-sectional schematic diagram illustrating an example of a configuration of an imaging device according to a modification example 5 of the present disclosure.

FIG. 16 is an exploded perspective view of a schematic configuration of an imaging device according to a second embodiment of the present disclosure.

FIG. 17 is a diagram illustrating an example of a circuit configuration of the imaging device illustrated in FIG. 16.

FIG. 18A is a diagram describing that a sensor pixel, an analog circuit of a second substrate, and a logic circuit of a third substrate are coupled to each other in the imaging device illustrated in FIG. 16.

FIG. 18B is a diagram describing that a logic circuit of the second substrate and the logic circuit and DRAM of the third substrate are coupled in the imaging device illustrated in FIG. 16.

FIG. 19 is an exploded perspective view of a schematic configuration of an imaging device according to a third embodiment of the present disclosure.

FIG. 20 is a diagram illustrating an example of a schematic configuration of an imaging system including the imaging device according to any of the first to third embodiments and the modification examples 1 to 5 described above.

FIG. 21 is a diagram illustrating an example of an imaging procedure of the imaging system in FIG. 20.

FIG. 22 is a block diagram depicting an example of schematic configuration of a vehicle control system.

FIG. 23 is a diagram of assistance in explaining an example of installation positions of an outside-vehicle information detecting section and an imaging section.

FIG. 24 is a view depicting an example of a schematic configuration of an endoscopic surgery system.

FIG. 25 is a block diagram depicting an example of a functional configuration of a camera head and a camera control unit (CCU).

### MODES FOR CARRYING OUT THE INVENTION

The following describes an embodiment of the present disclosure in detail with reference to the drawings. The following description is a specific example of the present disclosure, but the present disclosure is not limited to the following modes. In addition, the present disclosure is not also limited to the disposition, dimensions, dimension ratios, and the like of the respective components illustrated in the respective diagrams. It is to be noted that description is given in the following order.

1. First Embodiment (an example of an imaging device in which an analog circuit provided in a second substrate includes a transistor that operates in a full depletion mode)

### 1-1. Configuration of Imaging Device

### 1-2. Method of Manufacturing Imaging Device

### 1-3. Workings and Effects

### 2. Modification Examples

2-1. Modification Example 1 (another example of a structure of a transistor provided in a second substrate)
2-2. Modification Example 2 (an example in which a plurality of second substrates is stacked)
2-3. Modification Example 3 (an example in which one of a plurality of second substrates is provided with a pixel circuit)
2-4. Modification Example 4 (an example in which a second substrate is provided with a functional element)
2-5. Modification Example 5 (an example in which a first substrate and a second substrate are bonded face to face)
3. Second Embodiment (an example of an imaging device in which an analog circuit and a logic circuit are electrically coupled to each other for each of pixels)
4. Third Embodiment (an example of wafer on wafer on wafer (WoWoW))

### 5. Application Example

### 6. Practical Application Examples

### 1. FIRST EMBODIMENT

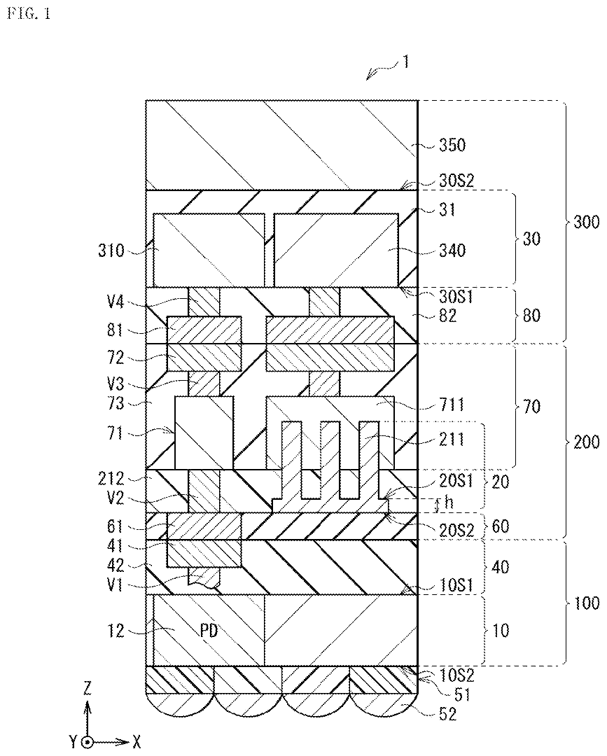

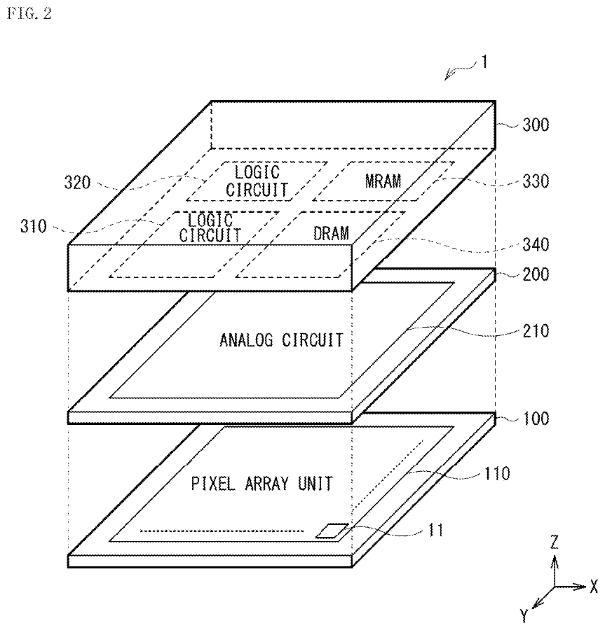

FIG. 1 schematically illustrates an example of a cross-sectional configuration of an imaging device (imaging device 1) according to a first embodiment of the present disclosure. FIG. 2 is an exploded perspective view of a schematic configuration of the imaging device 1 illustrated in FIG. 1. The imaging device 1 has a three-dimensional structure in which three substrates including a first substrate 100, a second substrate 200, and a third substrate 300 are stacked in this order. The imaging device 1 is a back-illuminated imaging device in which light comes from a back surface side of the first substrate 100. The imaging device 1 according to the present embodiment includes a transistor that operates in a full depletion mode as a transistor of the second substrate 200.

### (1-1. Configuration of Imaging Device)

In the imaging device 1, the first substrate 100, the second substrate 200, and the third substrate 300 are stacked in this order as described above. The first substrate 100 includes a pixel array unit 110 in which a plurality of sensor pixels 11 is disposed in an array. The second substrate 200 is provided, for example, with an analog circuit 210 that is electrically coupled to the pixel array unit 110. This analog circuit 210 includes a transistor that operates in the full depletion mode. The third substrate 300 is provided, for example, with logic circuits (logic circuits 310 and 320) and memories such as a Magnetoresistive Random Access Memory (MRAM) 330 and a Dynamic Random Access Memory (DRAM) 340 that are electrically coupled to the analog circuit 210 described above.

The first substrate 100 includes a semiconductor substrate 10 and a wiring layer 40. The semiconductor substrate 10 has a first surface (front surface) 10S1 and a second surface (back surface or light incidence surface) 10S2 that are opposed to each other. The wiring layer 40 is provided on the first surface 10S1 side of the semiconductor substrate 10. The second surface 10S2 side of the semiconductor substrate 10 is provided, for example, with a color filter 51 and a light receiving lens 52. The second substrate 200 includes a semiconductor substrate 20 and wiring layers 60 and 70. The semiconductor substrate 20 has a first surface (front surface) 20S1 and a second surface (back surface) 20S2 that are opposed to each other. The first surface 20S1 side and the second surface 20S2 side of the semiconductor substrate 20 are respectively provided with the wiring layer 70 and the wiring layer 60. The first substrate 100 and the second substrate 200 are stacked with the wiring layer 40 and the wiring layer 60 interposed in between. The wiring layer 40 is provided on the first surface 10S1 side of the semiconductor substrate 10. The wiring layer 60 is provided on the second surface 20S2 side of the semiconductor substrate 20. In other words, the first substrate 100 and the second substrate 200 are stacked face to back. In the third substrate 300, a semiconductor substrate 30 and a wiring layer 80 are stacked on a support substrate 350 in this order. The third substrate 300 and the second substrate 200 are stacked with the wiring layer 70 and the wiring layer 80 interposed in between. The wiring layer 70 is provided on the first surface 20S1 side of the semiconductor substrate 20. The wiring layer 80 is provided on a first surface (front surface) 30S1 side of the semiconductor substrate 30. In other words, the second substrate 200 and the third substrate 300 are stacked face to face.

As described above, the first substrate 100 includes the pixel array unit 110 in which the plurality of sensor pixels 11 is disposed in an array. For example, photodiodes PD (light receiving elements 12) are formed in the plurality of sensor pixels 11 to be buried in the semiconductor substrate 10. The photodiodes PD (light receiving elements 12) each perform photoelectric conversion. Although not illustrated, the semiconductor substrate 10 is further provided, for example, with one floating diffusion FD, one transfer transistor TR, or the like for each of the sensor pixels 11. Alternatively, the semiconductor substrate 10 is further provided with the one floating diffusion FD, the one transfer transistor TR, or the like for the plurality of sensor pixels 11. In the wiring layer 40, for example, a wiring line that is coupled to the floating diffusion FD, a wiring line including a gate of the transfer transistor TR, and the like are formed in an interlayer insulating layer 42. One or more pad electrodes 41 are exposed on a surface (specifically, a surface of the interlayer insulating layer 42) of the wiring layer 40. The one or more pad electrodes 41 are used, for example, to bond and electrically couple the first substrate 100 to the second substrate 200. Although not illustrated, these pad electrodes 41 are each coupled to the floating diffusion FD and the gate of the transfer transistor TR, for example, through a via V1.

The second substrate 200 is provided with the analog circuit 210 as described above. The analog circuit 210 is, for example, a portion of an analog digital converter (ADC) of the imaging device 1, a control section that controls each of sections in the imaging device 1, or the like. The analog circuit 210 includes a circuit component that is supplied with a power supply voltage for the analog circuit. Specifically, the analog circuit 210 includes a variety of transistors (pixel circuits), a vertical drive circuit, a comparator and a counter of the ADC, a reference voltage supply section, a Phase Locked Loop (PLL) circuit, and the like. The variety of transistors (pixel circuits) read out analog pixel signals from the sensor pixels 11. The vertical drive circuit drives the sensor pixels 11 row by row. The sensor pixels 11 are two-dimensionally arranged in a lattice in row and column directions. The reference voltage supply section supplies the comparator with a reference voltage.

In the present embodiment, a transistor provided in the second substrate 200 has a transistor structure in which the transistor operates in the full depletion mode. Examples of the transistor that operates in the full depletion mode include Fin-FET. The Fin-FET includes a plurality of fins 211 and a gate 711. The plurality of fins 211 includes, for example, the semiconductor substrate 20.

Fins 221 each have a flat plate shape. For example, the plurality of fins 221 stands, for example, on the semiconductor substrate 20. In other words, the plurality of fins 221 is each supported by the semiconductor substrate 20. The plurality of fins 221 is disposed, for example, in an X axis direction and each extends in a Y axis direction. There is provided an insulating film including, for example, SiO₂ on the semiconductor substrate 20. The insulating film is included in an element isolation region 212 described below. The fins 221 stand to penetrate this insulating film. In other words, a portion of each of the fins 221 is buried in the insulating film. A side surface and an upper surface of the fin 221 exposed from the insulating film are covered with a gate insulating film (not illustrated) including, for example, HfSiO, HfSiON, TaO, TaON, or the like. The gate 711 extends across the plurality of fins 221 in the X axis direction intersecting an extending direction (Y axis direction) of the fins 221. A channel region is formed at a portion of each of the fins 221 at which the fin 221 intersects the gate 711. Source/drain regions are formed at both ends of the fin 221 with the channel region interposed in between.

The semiconductor substrate 20 is divided into a plurality of portions, for example, by the element isolation region 212 having, for example, a Shallow Trench Isolation (STI) structure, a Deep Trench Isolation (DTI), or Full Trench Isolation (FTI) structure. The respective portions of the semiconductor substrate 20 divided by the element isolation region 212 are provided with transistors that each operate in the full depletion mode like the Fin-FET described above. A thickness (h) of the semiconductor substrate 20 that couples the plurality of fins 221 to each other is, for example, 1 μm or less (FIG. 1).

It is to be noted that the semiconductor substrate 20 extending in an XY plane direction is for supporting the plurality of fins 221 as described above. The thickness (h) of the semiconductor substrate 20 is not therefore limited to the above. The thickness (h) of the semiconductor substrate 20 may be, for example, 100 nm or less. Alternatively, the thickness (h) of the semiconductor substrate 20 may be 20 nm or less. In a case where the semiconductor substrate 20 has a thickness of about 20 nm, it is possible for the semiconductor substrate 20 to sufficiently support the plurality of fins. In addition, in the present embodiment, no impurity region is formed in the semiconductor substrate 20 extending in the XY plane direction, but an impurity region may be formed by implanting ions.

One or more pad electrodes 61 are exposed on a surface of the wiring layer 60. The one or more pad electrodes 61 are used, for example, to bond and electrically couple the second substrate 200 to the first substrate 100. In the wiring layer 70, a wiring line 71 or the like is formed in an interlayer insulating layer 73. The wiring line 71 includes the gate 711 of the Fin-FET described above. One or more pad electrodes 72 are exposed on a surface (specifically, a surface of the interlayer insulating layer 73) of the wiring layer 70. The one or more pad electrodes 72 are used, for example, to bond and electrically couple the second substrate 200 to the third substrate 300. These pad electrodes 61 and 72 exposed on the surfaces of the second substrate 200 on the first substrate 100 side and the third substrate 300 side are electrically coupled to each other by a via V2, the wiring line 71, and a via V3. The via V2 penetrates the element isolation region 212. The wiring line 71 is provided in the same layer as that of the gate 711. The via V3 is provided between the wiring line 71 and the pad electrode 72.

As described above, in the third substrate 300, the semiconductor substrate 30 and the wiring layer 80 are stacked on the support substrate 350 in this order. The first surface 30S1 of the semiconductor substrate 30 is provided, for example, with the logic circuits 310 and 320, the MRAM 330, the DRAM 340, and the like. The logic circuits 310 and 320 are different from each other in technology node. Each of the logic circuits is provided with a circuit that performs various kinds of signal processing on data resulting from photoelectric conversion or data resulting from an imaging operation by the imaging device 1. In addition, the logic circuit may include a circuit component that is a portion of the ADC, the control section, or the like and is supplied with a power supply voltage for the logic circuit.

It is to be noted that the power supply voltages for the circuits (e.g., the logic circuits 310 and 320) provided in the third substrate 300 are preferably lower than the power supply voltage for the circuit (e.g., the analog circuit 210) provided in the second substrate 200. In other words, it is preferable that the third substrate 300 be provided with the logic circuits 310 and 320 each of which includes a transistor that is driven by using a power supply voltage lower than a power supply voltage of a transistor included in the analog circuit 210 provided in the second substrate 200. This is not, however, limitative. The third substrate 300 may be further provided with a circuit (e.g., an analog circuit) including a transistor that is driven by using a higher power supply voltage than the power supply voltage of the transistor provided in the second substrate 200. Alternatively, a circuit including a transistor that is driven by using a lower power supply voltage than the power supply voltage of the transistor provided in the third substrate 300 may be further formed in the second substrate 200.

The wiring layer 80 is provided on the first surface 30S1 side of the semiconductor substrate 30. One or more pad electrodes 81 are exposed on a surface (specifically, a surface of an interlayer insulating layer 82) of the wiring layer 80. The one or more pad electrodes 81 are used, for example, to bond and electrically couple the third substrate 300 to the second substrate 200. Each of the plurality of pad electrodes 81 is coupled to the logic circuit 310 or 320, the MRAM 330, or the DRAM 340, for example, through a via V4.

The first substrate 100, the second substrate 200, and the third substrate 300 are joined together and electrically coupled by bonding pad electrodes to each other that are exposed on the surfaces opposed to each other. Each of the pad electrodes (the pad electrodes 41, 61, 72, and 81) is formed by using, for example, metal such as Cu (copper). In other words, the first substrate 100 and the second substrate 200, and the second substrate 200 and the third substrate 300 are bonded to each other by metal bonding (e.g., Cu—Cu bonding).

### (1-2. Method of Manufacturing Imaging Device)

It is possible to manufacture the imaging device 1 according to the present embodiment, for example, as follows.

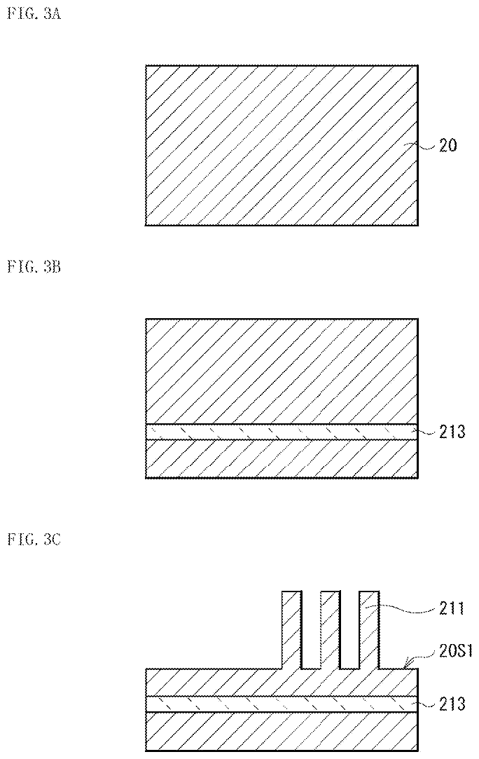

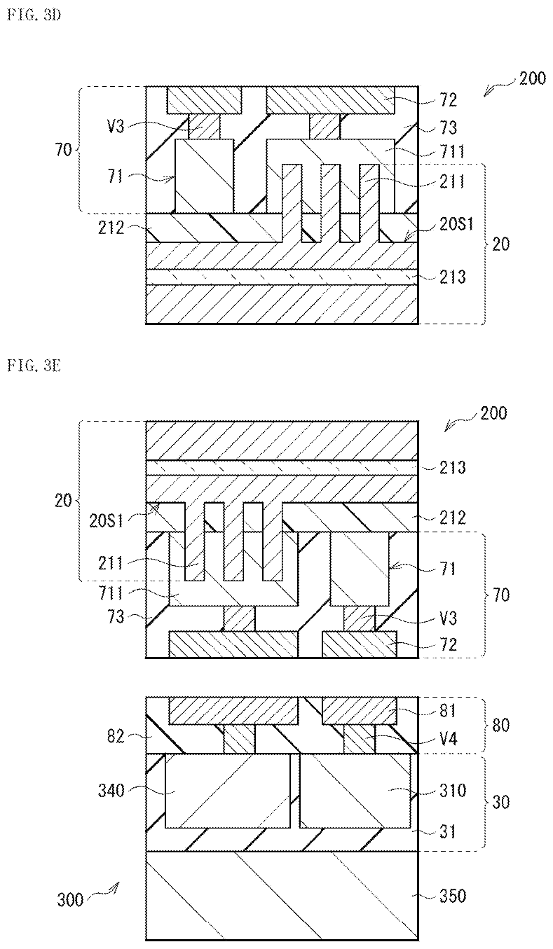

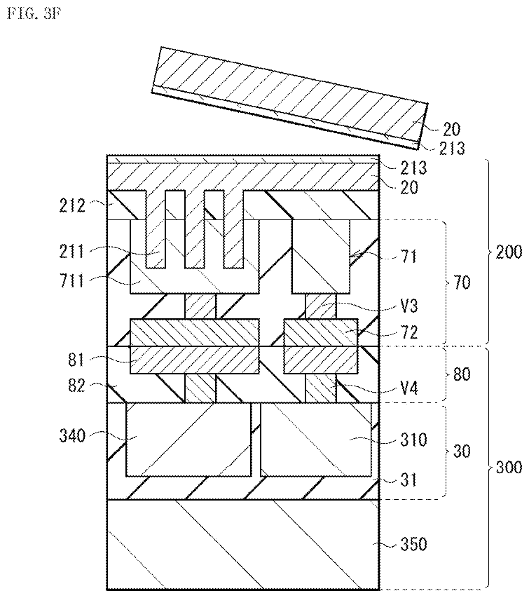

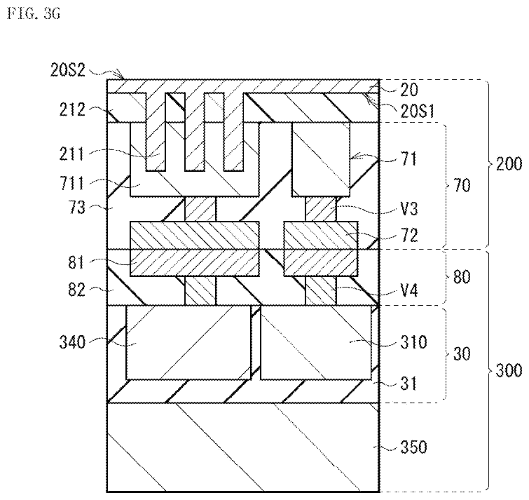

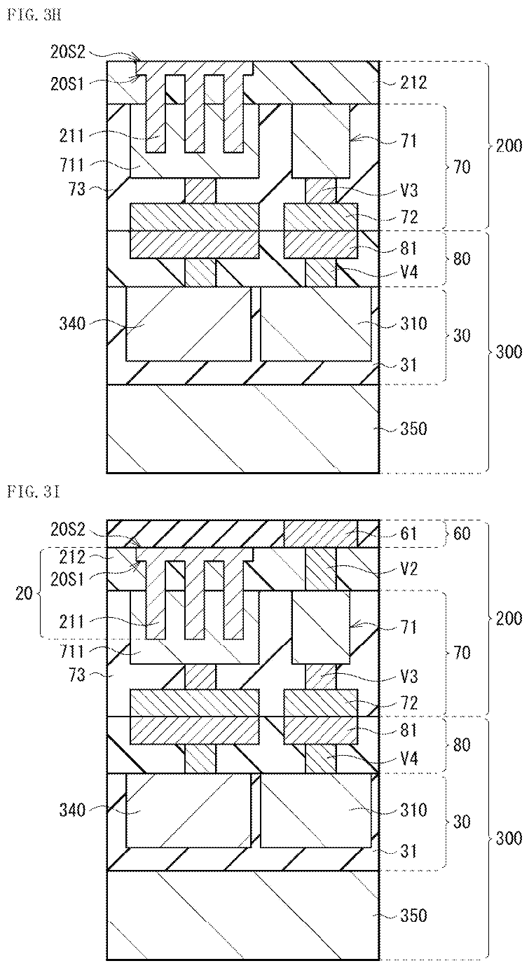

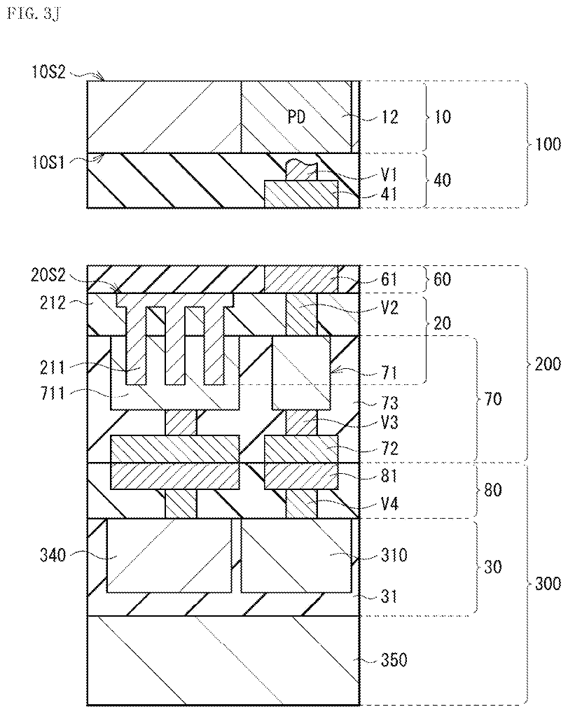

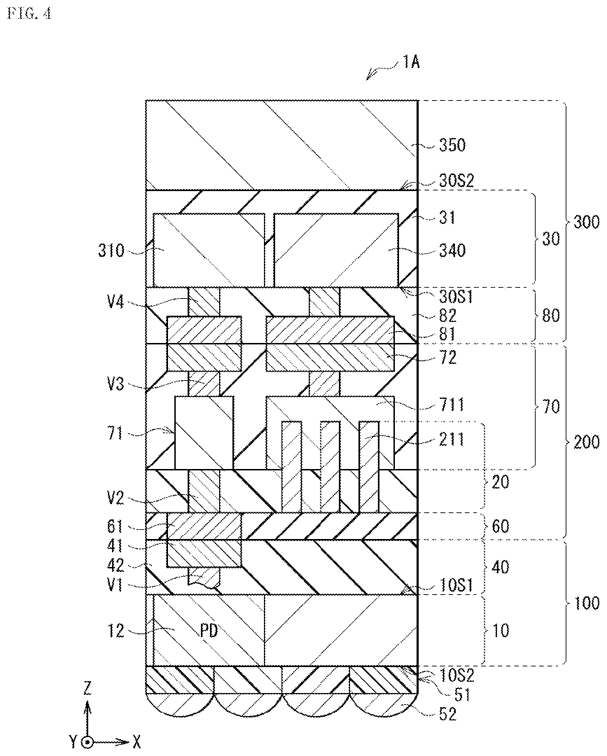

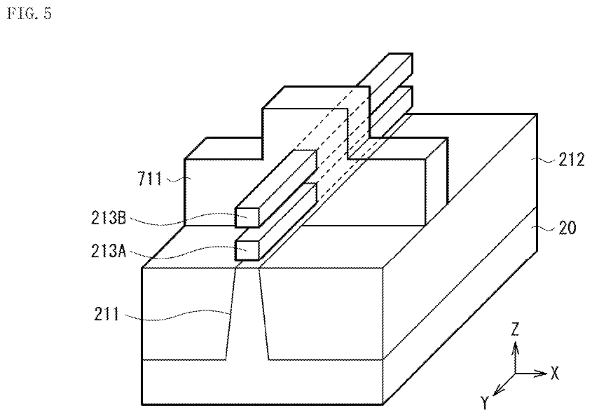

First, as illustrated in FIG. 3A, a silicon (Si) substrate is, for example, prepared as the semiconductor substrate 20. Subsequently, as illustrated in FIG. 3B, a fragile layer 213 is formed at a predetermined depth in the semiconductor substrate 20, for example, by implanting hydrogen (H) ions. Specifically, the fragile layer 213 is formed, for example, at a position that is about 30 nm to 50 nm deeper than lower portions of the fins 211.

Next, as illustrated in FIG. 3C, the semiconductor substrate 20 is processed to form the plurality of fins 211. Subsequently, as illustrated in FIG. 3D, the element isolation region 212 and the wiring layer 70 are formed on the first surface 20S1 of the semiconductor substrate 20. The wiring layer 70 includes the wiring line 71, the via V3, and the interlayer insulating layer 73. The wiring line 71 includes the gate 711. The pad electrode 72 is exposed on the front surface of the interlayer insulating layer 73.

Next, as illustrated in FIG. 3E, the third substrate 300 is separately fabricated on the support substrate 350. The semiconductor substrate 30 and the wiring layer 80 are stacked in the third substrate 300 in this order. The semiconductor substrate 30 is provided with the logic circuits 310 and 320, the MEAM 330, and the DRAM 340. The wiring layer 80 includes the plurality of pad electrodes 81. Subsequently, as illustrated in FIG. 3E, the wiring layer 70 of the second substrate 200 and the wiring layer 80 of the third substrate 300 are disposed face to face. The pad electrodes 72 and 81 exposed on the respective surfaces are bonded.

Next, as illustrated in FIG. 3F, the semiconductor substrate 20 above the fragile layer 213 is peeled off. Subsequently, as illustrated in FIG. 3G, the semiconductor substrate 20 is decreased in thin film to a predetermined thickness (e.g., 1 μm or less), for example, by chemical mechanical polishing (CMP). Next, as illustrated in FIG. 3H, the semiconductor substrate 20 is divided into a plurality of portions. The element isolation region 212 is formed between the respective portions.

Subsequently, as illustrated in FIG. 3I, the via V2 is formed that penetrates the element isolation region 212 and comes into contact with the wiring line 71 and the wiring layer 60 including the pad electrode 61 is then formed on the second surface 20S2 of the semiconductor substrate 20 including the element isolation region 212.

Next, as illustrated in FIG. 3J, the first substrate 100 is separately fabricated on the first surface 1051 of the semiconductor substrate 10 in which the photodiode PD (light receiving element 12) is formed to be buried. The first substrate 100 is provided with the wiring layer 40. The wiring layer 40 includes the via V1 and the like therein. In addition, the wiring layer 40 includes the interlayer insulating layer 42. The pad electrode 41 is exposed on the front surface of the interlayer insulating layer 42. Subsequently, as illustrated in FIG. 3J, the wiring layer 40 of the first substrate 100 and the wiring layer 60 of the second substrate 200 are disposed face to face. The pad electrodes 41 and 61 exposed on the respective surfaces are bonded. After that, the color filter 51 and the light receiving lens 52 are formed on the second surface 10S2 side of the first substrate 100. The imaging device 1 illustrated in FIG. 1 is thus completed.

It is to be noted that the method of manufacturing the imaging device 1 described above is an example, but this is not limitative. For example, a Silicon on Insulator (SOI) substrate may be used as the semiconductor substrate 20. A silicon oxide layer between a Si substrate and a Si layer of a surface may be used as the fragile layer 213. In addition, the fragile layer 213 does not necessarily have to be provided. The semiconductor substrate 20 may be decreased in thin film by CMP alone. In addition, the semiconductor substrate 20 may be decreased in thin film by using dry etching, wet etching, or the like.

### (1-3. Workings and Effects)

In the imaging device 1 according to the present embodiment, the analog circuit 210 provided in the second substrate 200 includes a transistor that operates in the full depletion mode. The second substrate 200 is stacked on and electrically coupled to the first substrate 100 including the plurality of sensor pixels 11. This reduces a thickness of the second substrate 200. The following describes this.

In recent years, an image sensor has adopted a structure in which a sensor section and a control circuit section (logic circuit) are formed on different wafers and the wafers are stacked. For this reason, the sensor has tended to include a larger number of signal processing circuits and the like for correction and include a larger number of necessary memories for holding information to be processed. To address this, an imaging device has been developed that has a structure in which chips are stacked in three or more layers or a wafer (a multichip in which a variety of functions are integrated in one chip) provided with a memory circuit, a logic circuit, and the like is stacked on a wafer provided with a plurality of solid-state imaging elements as described above.

However, in a case where the multichip is stacked on the image sensor in which the wafer provided with the sensor section and the wafer provided with the control circuit section described above are stacked, an intermediate wafer and upper and lower wafers are electrically coupled to each other by a through electrode (TSV). TSV provided in a typical image sensor having a three-layer stacked structure has a depth of 10 μm or more. The TSV having a depth of 10 μm or more has, for example, a diameter (φ) of 3 μm or more. This leads to an increase in circuit area in the image sensor. Alternatively, the TSV having a diameter (φ) of 3 μm or more prevents a circuit pitch from being reduced. In addition, the TSV penetrates the Si substrate. This adds parasitic capacitance. This increase in parasitic capacitance may decrease characteristics of the sensor section and the circuit provided in the intermediate wafer.

To form TSV having a small diameter (φ) or decrease an aspect ratio of TSV, a substrate of the intermediate wafer may be decreased in thin film. It is, however, necessary to hold a well to guarantee an operation of a transistor (bulk transistor) provided in the intermediate wafer. Further, a film thickness of about 10 μm is typically necessary to avoid a short circuit or the like caused by a circuit operation or a substrate interface defect after the thin film is decreased. Decreasing the substrate in thin film thus has a limit.

In contrast, in the imaging device 1 according to the present embodiment, a transistor that operates in the full depletion mode or Fin-FET, for example, is used as a transistor included in the analog circuit 210 provided in the second substrate 200. This makes it possible to reduce the thickness of the semiconductor substrate 20 extending in the XY plane direction of the second substrate 200 as compared with a case where the transistor provided in the analog circuit 210 is a typical transistor having a planar structure or a so-called bulk transistor. In other words, it is possible to reduce the thickness of the second substrate 200.

It is thus possible to considerably reduce formation area of a through wiring line (e.g., TSV) for electrically coupling, for example, the first substrate 100 and the third substrate 300 in the imaging device 1 according to the present embodiment. This makes it possible to achieve miniaturization.

In addition, it is possible in the imaging device 1 according to the present embodiment to significantly reduce the parasitic capacitance caused by the through wiring line.

The following describes modification examples (modification examples 1 to 5) of the first embodiment described above and second and third embodiments. It is to be noted that the following description denotes the same components as those of the first embodiment described above with the same signs and the descriptions thereof are omitted as appropriate.

### 2. MODIFICATION EXAMPLES

### 2-1. Modification Example 1

FIG. 4 schematically illustrates an example of a cross-sectional configuration of an imaging device (imaging device 1A) according to the modification example 1 of the present disclosure. In the first embodiment described above, the example has been described in which the plurality of fins 211 stands on the semiconductor substrate 20 as a transistor that is included in the analog circuit 210 provided in the second substrate 200 and operates in the full depletion mode. The plurality of fins 211 may be, however, independent of each other as illustrated in FIG. 4. This makes it possible to further reduce the thickness of the second substrate 200.

In addition, in the first embodiment described above, a transistor having the Fin-FET structure has been exemplified as the transistor that operates in the full depletion mode, but this is not limitative. It is possible to use a transistor having another three-dimensional structure.

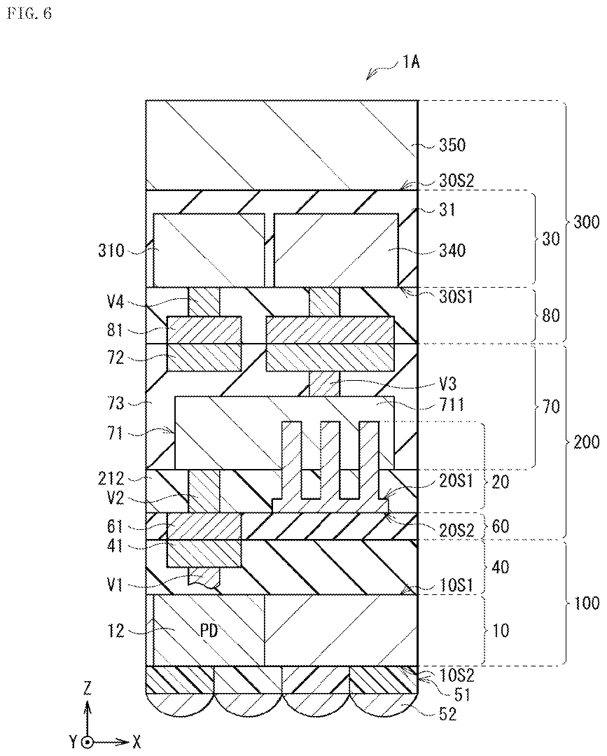

FIG. 5 schematically illustrates a structure of a transistor having a gate-all-around (GAA) structure as an example of the transistor having the other three-dimensional structure. The transistor having the GAA structure is provided with the fin 211, for example, on the semiconductor substrate 20. The fin 211 serves as a base. There are provided channels 213A and 213B each having a nano-wire shape above this fin 211. The channels 213A and 213B each extend, for example, in the Y axis direction. The gate 711 is provided around the channels 213A and 213B with a gate insulating film (not illustrated) interposed in between. It is to be noted that the transistor having the GAA structure illustrated in FIG. 5 may also be sometimes referred to as a nano-wire, a nanosheet, or a nanoribbon as another name.

Further, the transistor included in the analog circuit 210 provided in the second substrate 200 is not limited to the transistor having the three-dimensional structure. It is also possible to use, for example, a so-called planar transistor as long as the planar transistor operates in the full depletion mode.

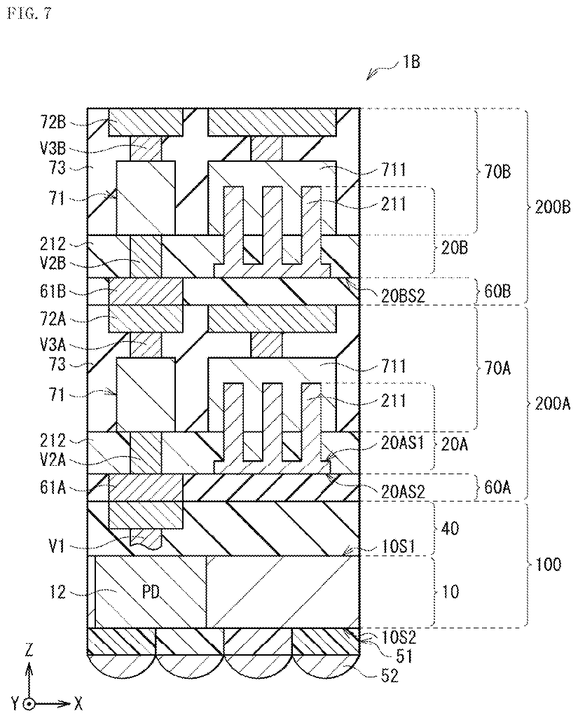

Still further, in the first embodiment described above, the example has been described in which the wiring line 71 provided in the same layer as that of the gate 711 of a transistor (Fin-FET in FIG. 1) included in the analog circuit 210 provided in the second substrate 200 is used as a portion of the wiring line that electrically couples the first substrate 100 and the third substrate 300, but this is not limitative. For example, as illustrated in FIG. 6, the gate 711 of a transistor included in the analog circuit 210 may be extended to cause the gate 711 and the via V2 to be coupled. The via V2 is coupled to the pad electrode 61. This makes it possible to increase the number of electrical coupling points between the first substrate 100 and the second substrate 200 and between the second substrate 200 and the third substrate 300. In other words, finer contacts are possible.

### 2-2. Modification Example 2

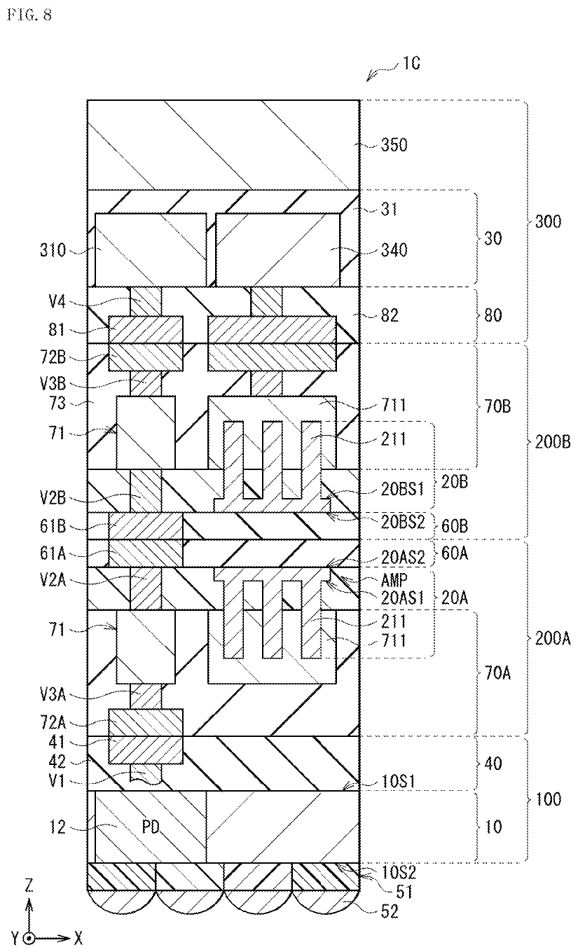

FIG. 7 schematically illustrates an example of a cross-sectional configuration of an imaging device (imaging device 1B) according to the modification example 2 of the present disclosure. In the first embodiment described above, the example has been described in which the one second substrate 200 including the analog circuit 210 including a transistor that operates in the full depletion mode is provided between the first substrate 100 and the third substrate 300. The two or more second substrates 200 (second substrates 200A and 200B) may be, however, stacked as illustrated in FIG. 7. This makes it possible to further facilitate miniaturization.

### 2-3. Modification Example 3

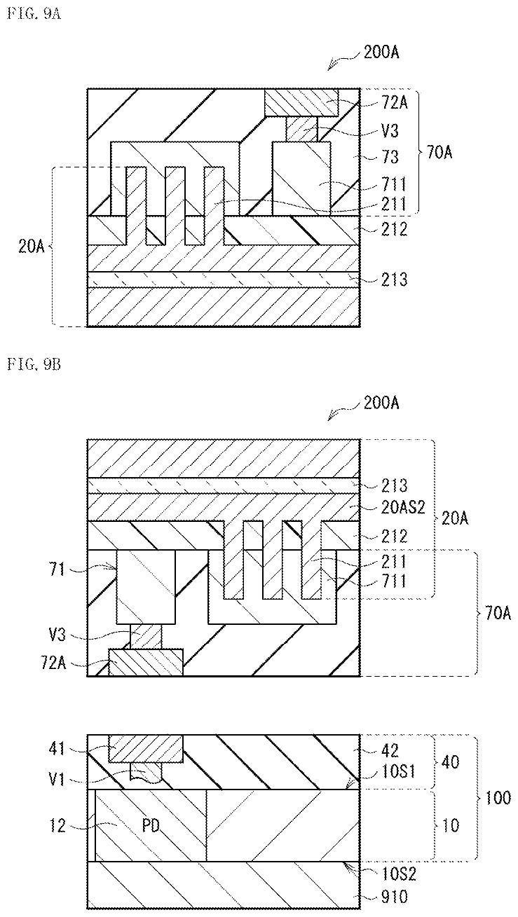

FIG. 8 schematically illustrates an example of a cross-sectional configuration of an imaging device (imaging device 1C) according to the modification example 3 of the present disclosure. In the modification example 2 described above, the plurality of second substrates 200 may be stacked, but one of the plurality of second substrates 200 may be provided with a pixel circuit as the analog circuit.

The pixel circuit outputs a pixel signal based on electric charge outputted from each of the sensor pixels 11. The pixel circuit includes, for example, three transistors. Specifically, the pixel circuit includes an amplification transistor AMP, a reset transistor RST, and a selection transistor SEL. In each of the sensor pixels 11, for example, a cathode of the photodiode PD (light receiving element 12) is electrically coupled to a source of the transfer transistor TR. An anode of the photodiode PD (light receiving element 12) is electrically coupled to a reference potential line (e.g., a ground line GND). A drain of the transfer transistor TR is electrically coupled to the floating diffusion FD.

The floating diffusion FD is electrically coupled to an input end of the pixel circuit. Specifically, the floating diffusion FD is electrically coupled, for example, to a gate of the amplification transistor AMP and a source of the reset transistor RST. A drain of the reset transistor RST is coupled to a power supply line VDD and a gate of the reset transistor RST is coupled, for example, to a drive signal line. A drain of the amplification transistor AMP is coupled to the power supply line VDD and a source of the amplification transistor AMP is coupled to a drain of the selection transistor SEL. A source of the selection transistor SEL is coupled to a vertical signal line and a gate of the selection transistor SEL is coupled, for example, to the drive signal line.

In a case where the transfer transistor TR is turned on, the transfer transistor TR transfers electric charge of the photodiode PD to the floating diffusion FD.

The reset transistor RST resets a potential of the floating diffusion FD to a predetermined potential. In a case where the reset transistor RST is turned on, the reset transistor RST resets the potential of the floating diffusion FD to the power supply line VDD.

The selection transistor SEL controls a timing at which a pixel signal is outputted from the pixel circuit.

The amplification transistor AMP generates, as the pixel signal, a signal of a voltage corresponding to a level of the electric charge held in the floating diffusion FD. The amplification transistor AMP is included in a source follower type amplifier. The amplification transistor AMP outputs the pixel signal of the voltage corresponding to the level of the electric charge generated in the photodiode PD (light receiving element 12). In a case where the selection transistor SEL is turned on, the amplification transistor AMP amplifies the potential of the floating diffusion FD and outputs a voltage corresponding to the potential, for example, to a logic circuit through the vertical signal line. The logic circuit is described below.

The amplification transistor AMP, the reset transistor RST, and the selection transistor SEL are provided on a first surface 20SA1 of a semiconductor substrate 20A. The second substrate 200A is stacked with the first surface 20SA1 of the semiconductor substrate 20A opposed to the first substrate 100. In other words, the first substrate 100 and the second substrate 200A are stacked face to face.

It is possible to manufacture the imaging device 1C, for example, as follows. It is to be noted that a method of manufacturing the imaging device 1 described below is an example, but this is not limitative.

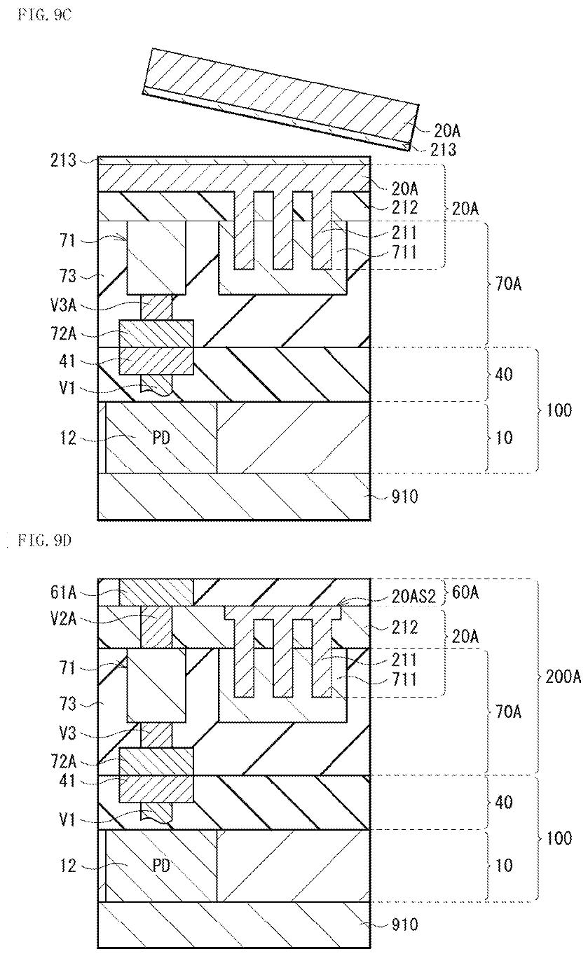

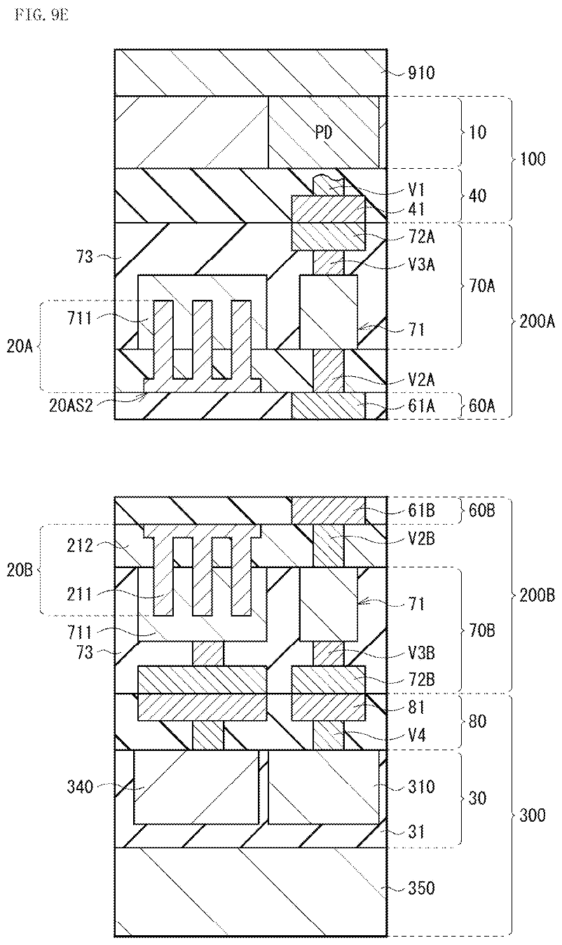

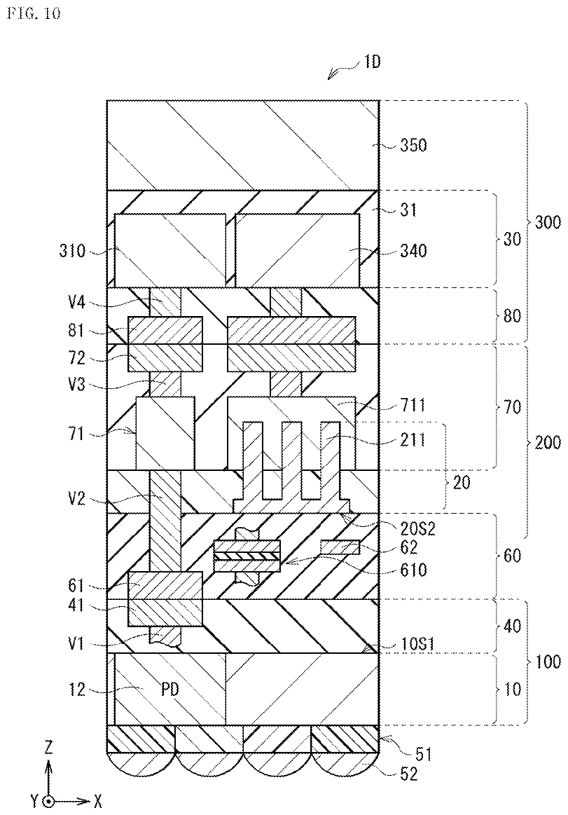

First, as illustrated in FIG. 9A, the second substrate 200A provided with the amplification transistor AMP, the reset transistor RST, and the selection transistor SEL is formed as in the diagrams up to FIG. 3D in the first embodiment described above.

Subsequently, as illustrated in FIG. 9B, the first substrate 100 is separately fabricated on the first surface 10S1 of the semiconductor substrate 10 that is provided on a support substrate 910 and has the photodiode PD (light receiving element 12) formed to cause the photodiode PD (light receiving element 12) to be buried therein. The first substrate 100 is provided with the wiring layer 40. The wiring layer 40 includes the via V1 and the like. In addition, the wiring layer 40 includes the interlayer insulating layer 42. The pad electrode 41 is exposed on the front surface of the interlayer insulating layer 42. Subsequently, as illustrated in FIG. 9B, the wiring layer 40 of the first substrate 100 and the wiring layer 70A of the second substrate 200A are disposed face to face. The pad electrodes 41 and 72A exposed on the respective surfaces are bonded.

Next, as illustrated in FIG. 9C, the semiconductor substrate 20A above the fragile layer 213 is peeled off and the semiconductor substrate 20A is then decreased in thin film to a predetermined thickness (e.g., 1 μm or less), for example, by CMP. Next, the semiconductor substrate 20A is divided into a plurality of portions. The element isolation region 212 is formed between the respective portions. Subsequently, as illustrated in FIG. 9D, a via V2A is formed that penetrates the element isolation region 212 and a wiring layer 60A including a pad electrode 61A is then formed on a second surface 20AS2 of the semiconductor substrate 20A including the element isolation region 212.

Next, as illustrated in FIG. 9E, the second substrate 200B is formed and then bonded to the separately fabricated third substrate 300 at pad electrodes 72B and 81 exposed on the respective surfaces as in the diagrams up to FIG. 3D in the first embodiment described above. After that, the pad electrodes 61A and 61B exposed on the respective surfaces of the second substrate 200A and the second substrate 200B are bonded and the support substrate 910 is then peeled off. The color filter 51 and the light receiving lens 52 are formed on the first surface 10S1 side of the first substrate 100. The imaging device 1C illustrated in FIG. 8 is thus completed.

### 2-4. Modification Example 4

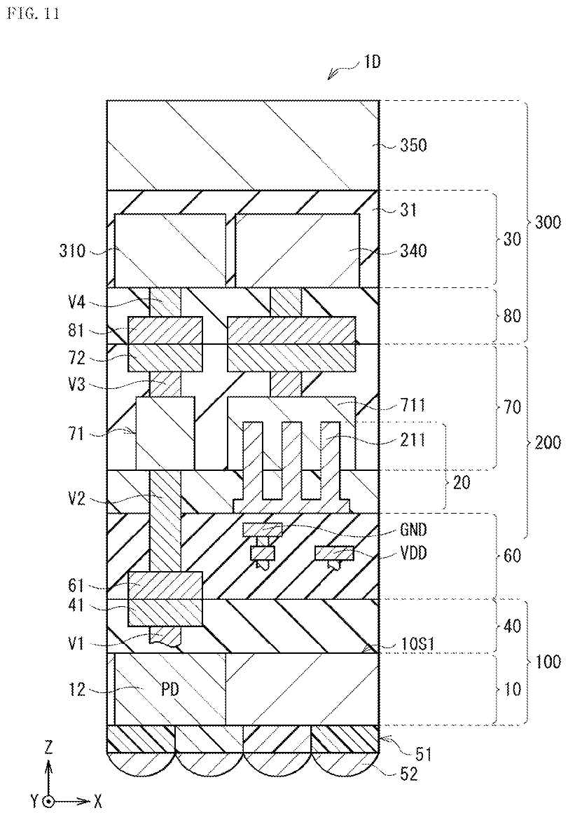

FIG. 10 schematically illustrates an example of a cross-sectional configuration of an imaging device (imaging device 1D) according to the modification example 4 of the present disclosure. The wiring layer 60 on the second surface 20S2 side of the semiconductor substrate 20 may be further provided with a functional element 610. Examples of the functional element 610 include a capacitance element such as a passive element, a Metal-Insulator-Metal (MIM), a Metal-Oxide-Metal (MOM), a ferroelectric memory (FeRAM), and DRAM, an inductor element, and a variable resistance element such as MRAM, a Resistive Random Access Memory (ReRAM), and a Phase Change Random Access Memory (PCRAM). In addition, the wiring layer 60 may be provided with wiring lines 62 such as the power supply line VDD, the ground line GND, and the signal line. Each of the wiring lines 62 may be provided in a single layer or may be provided over a plurality of layers.

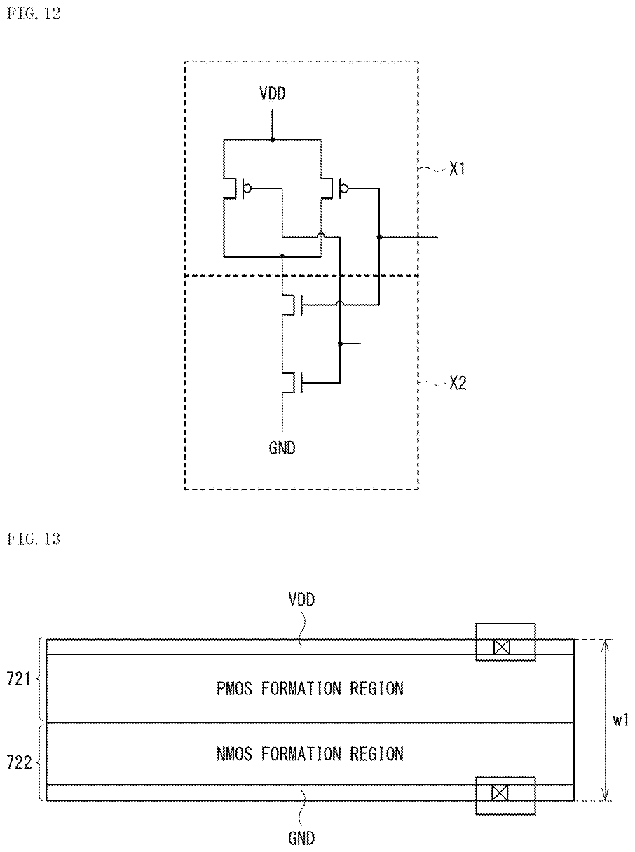

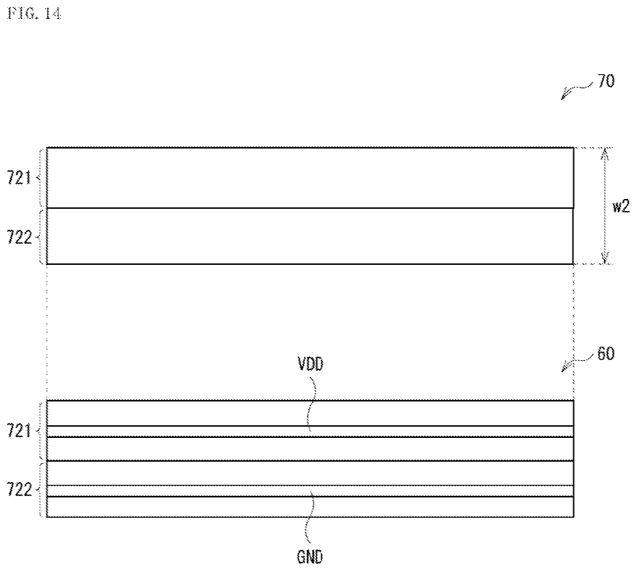

FIG. 11 schematically illustrates a cross-sectional configuration in which the wiring layer 60 is provided with the power supply line VDD and the ground line GND as another example of the present modification example. In a typical imaging device, the wiring layer 70 is provided with an inverter Inv, a NAND circuit (FIG. 12), a NOR circuit, or a flip-flop obtained by combining them as a standard cell (logic circuit block). Specifically, a PMOS formation region 721 illustrated in FIG. 13 is provided, for example, with a circuit portion X1 that is illustrated in FIG. 12 and includes PMOS. An NMOS formation region 722 illustrated in FIG. 13 is provided, for example, with a circuit portion X2 that is illustrated in FIG. 12 and includes NMOS. The wiring layer 70 is further provided with the power supply line VDD, the ground line GND, the signal line, and the like. The power supply line VDD and the ground line GND are respectively disposed at ends of the PMOS formation region 721 and the NMOS formation region as illustrated in FIG. 13 by taking into consideration the IR drop, a contact between wiring lines, and the like. This is a cause of a limit on the wiring layout, an increase in layout area, and an increase in cost caused by increasing wiring layers.

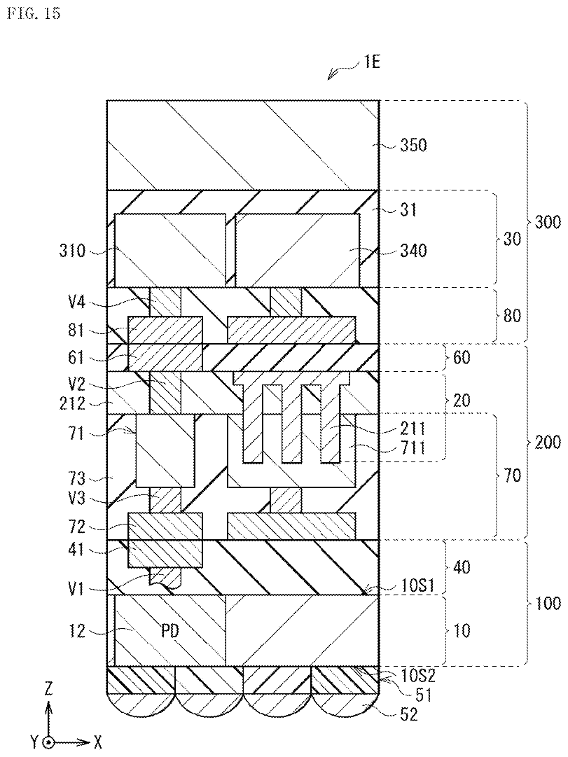

In contrast, in the present modification example, as illustrated in FIGS. 11 and 14, the wiring layer 60 on the first substrate 100 side is also provided with the power supply line VDD and the ground line GND as the wiring lines 62. This makes it possible to make a width w2 of a standard cell provided in the wiring layer 70 smaller than a width w1 (FIG. 13) of a standard cell in a typical imaging device. In other words, it is possible to further facilitate miniaturization.

In addition, providing the wiring layer 60 with the power supply line VDD and the ground line GND makes it possible to decrease, as compared with a typical imaging device, a wiring line length of a wiring line that electrically couples the power supply line VDD and the ground line GND, and a transistor provided in the second substrate 200. This makes it possible to reduce the influence of the IR drop and reduce the number of layers for the wiring lines provided, for example, in the wiring layer 70.

It is to be noted that FIGS. 11 and 14 each illustrate the example in which the power supply line VDD and the ground line GND extend side by side, but this is not limitative. For example, a layout may be adopted in which the power supply line VDD and the ground line GND cross each other. In other words, it is possible to increase a degree of freedom of the wiring layout. In addition, FIG. 11 illustrates the example in which the power supply line VDD and the ground line GND are provided in different layers, but this is not limitative. The power supply line VDD and the ground line GND may be provided in the same layer. This makes it possible to further reduce the influence of the IR drop and further reduce the number of layers for the wiring lines.

### 2-5. Modification Example 5

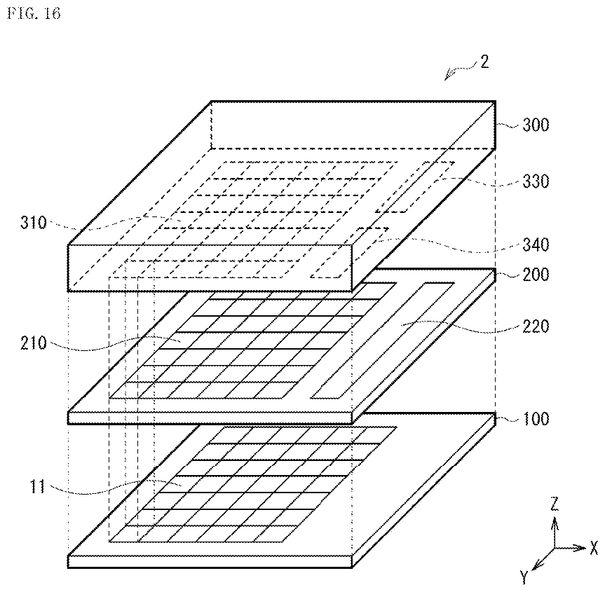

FIG. 15 schematically illustrates an example of a cross-sectional configuration of an imaging device (imaging device 1E) according to the modification example 5 of the present disclosure. In the first embodiment described above, the example has been described in which the first substrate 100 and the second substrate 200 are stacked face to back and the second substrate 200 and the third substrate 300 are stacked face to face, but this is not limitative. As illustrated in FIG. 15, the first substrate 100 and the second substrate 200 may be stacked face to face and the second substrate 200 and the third substrate 300 may be stacked face to back.

The configuration described above makes it possible to reduce parasitic capacitance caused by a wiring line (through wiring line) that electrically couples the second substrate 200 and the third substrate 300 and extends in a stack direction (Z axis direction).

### 3. SECOND EMBODIMENT

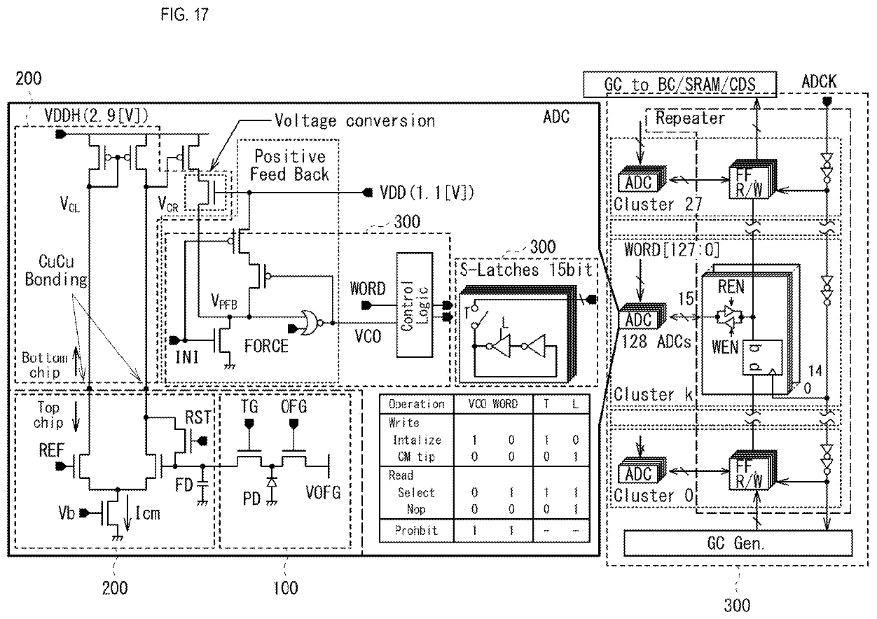

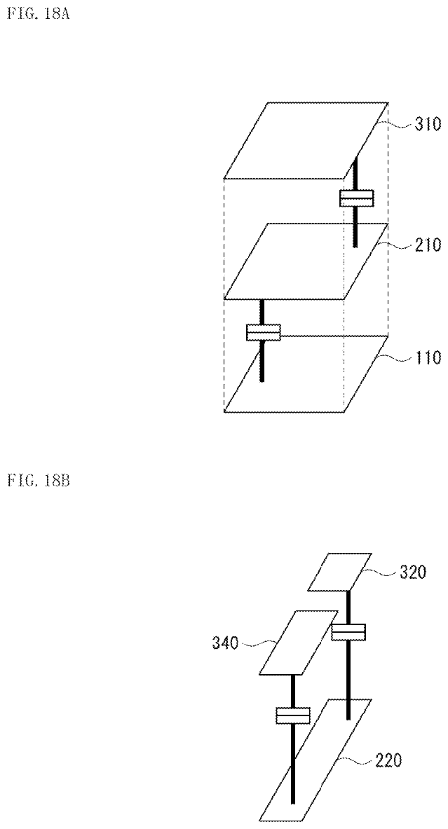

FIG. 16 is an exploded perspective view of a schematic configuration of an imaging device (imaging device 2) according to the second embodiment of the present disclosure. FIG. 17 illustrates an example of a circuit configuration of the imaging device 2. In the imaging device 2 according to the present embodiment, the analog circuit 210 provided in the second substrate 200 and the logic circuit 310 provided in the third substrate 300 are each coupled for each of the sensor pixels 11 through a pad electrode.

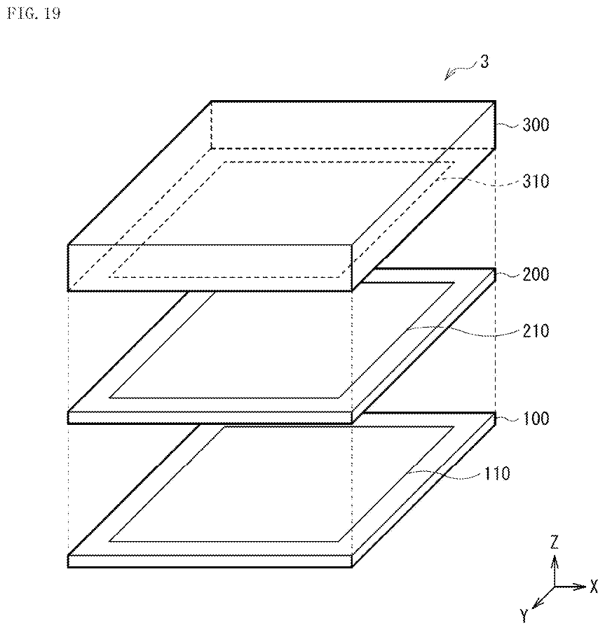

In the first embodiment described above, the example has been described in which the one analog circuit 210 is coupled to the plurality of sensor pixels 11 through the pad electrodes (FIG. 2). The analog circuit 210, however, includes a transistor that operates in the full depletion mode as a transistor included in the analog circuit 210 provided in the second substrate 200, thereby making it possible to bond the first substrate 100 and the second substrate 200 and the second substrate 200 and the third substrate 300 to each other at fine pitches by metal bonding. Specifically, as illustrated in FIG. 18A, it is possible to subject the one sensor pixel 11 and the analog circuit 210 provided in the second substrate 200 to metal bonding (e.g., Cu—Cu bonding) and subject this one analog circuit 210 provided in the second substrate 200 and the one logic circuit 310 provided in the third substrate 300 to metal bonding (e.g., Cu—Cu bonding). This makes it possible in the imaging device 2 according to the present embodiment to perform control in units of sensor pixels.

It is to be noted that FIG. 16 illustrates the example in which the third substrate 300 is provided with the logic circuit 320 and the DRAM 340. The logic circuit 320 is different from the logic circuit 310 in technology node. The logic circuit 320 and the DRAM 340, and the logic circuit 310 may be, however, coupled in a rewiring layer (RDL). In addition, as illustrated in FIG. 16, the second substrate 200 may be provided with a logic circuit 220 different from the logic circuit 310 in technology node. In that case, for example, as illustrated in FIG. 18B, the logic circuit 220 of the second substrate 200, and the logic circuit 320 and the DRAM 340 provided in the third substrate 300 may be electrically coupled to each other by metal bonding (e.g., Cu—Cu bonding).

In addition, FIG. 17 illustrates the example in which there is provided a latch memory section in the third substrate 300. The latch memory section may, however, include, for example, MRAM and be provided in the second substrate 200, for example, as in the modification example 4. In addition, the latch memory section may include a nonvolatile element such as ReRAM or PCRAM.

### 4. THIRD EMBODIMENT

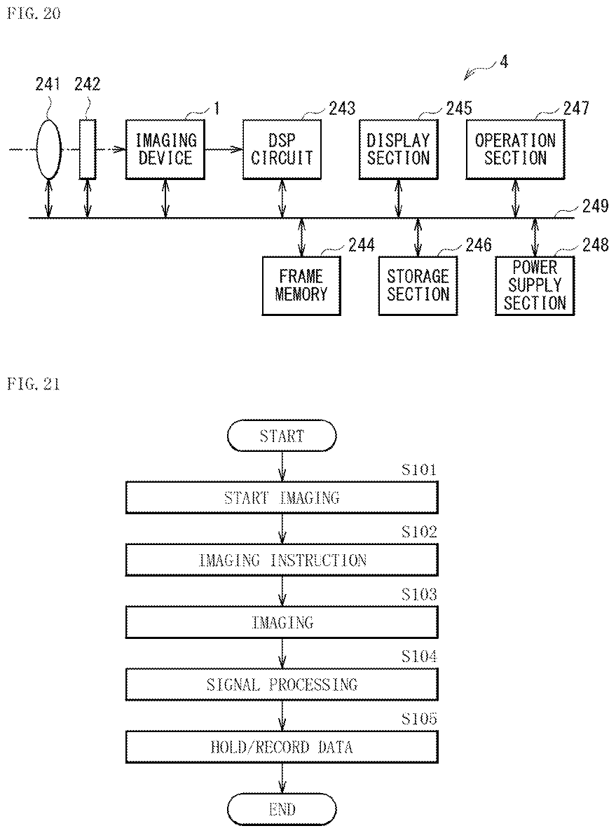

FIG. 19 is an exploded perspective view of a schematic configuration of an imaging device (imaging device 3) according to the third embodiment of the present disclosure. In any of the first and second embodiments and the modification examples 1 to 5 described above, the example has been described in which the third substrate 300 has a chip-on-wafer (CoW) structure in which the third substrate 300 includes a mixture of a plurality of chips of the logic circuits 310 and 320, the MRAM 330, the DRAM 340, and the like, but this is not limitative. As illustrated in FIG. 19, the third substrate 300 may be, for example, a wafer provided with the logic circuit 310 alone. In other words, the imaging device 3 is an imaging device having a wafer-on-wafer-on-wafer (WoWoW) structure.

### 5. APPLICATION EXAMPLE

FIG. 20 illustrates an example of a schematic configuration of an imaging system 4 including the imaging device (e.g., the imaging device 1) according to any of the first to third embodiments and the modification examples 1 to 5 described above.

The imaging system 4 is an electronic apparatus including, for example, a camera such as a digital still camera or a video camera, a portable terminal apparatus such as a smartphone or a tablet-type terminal, or the like. The imaging system 4 includes, for example, the imaging device (e.g., the imaging device 1) according to any of the first to third embodiments described above and the modification examples thereof, an optical system 241, a shutter device 242, a DSP circuit 243, a frame memory 244, a display section 245, a storage section 246, an operation section 247, and a power supply section 248. In the imaging system 4, the imaging device 1 according to any of the embodiments described above and the modification examples thereof, the DSP circuit 243, the frame memory 244, the display section 245, the storage section 246, the operation section 247, and the power supply section 248 are coupled to each other through a bus line 249.

The imaging device (e.g., the imaging device 1) according to any of the first to third embodiments described above and the modification examples thereof outputs image data corresponding to incident light. The optical system 241 includes one or more lenses. The optical system 241 guides light (incident light) from an object to the imaging device 1 to form an image on a light receiving surface of the imaging device 1. The shutter device 242 is disposed between the optical system 241 and the imaging device 1. The shutter device 242 controls a period in which the imaging device 1 is irradiated with light and a period in which light is blocked under the control of a drive circuit. The DSP circuit 243 is a signal processing circuit that processes a signal (image data) outputted from the imaging device 1. The frame memory 244 temporarily holds the image data processed by the DSP circuit 243 in units of frames. The display section 245 includes, for example, a panel-type display device such as a liquid crystal panel or an organic EL (Electro Luminescence) panel. The display section 245 displays a moving image or a still image captured by the imaging device 1. The storage section 246 records image data of the moving image or the still image captured by the imaging device 1 in a recording medium such as a semiconductor memory or a hard disk. The operation section 247 issues operation instructions for a variety of functions of the imaging system 4 in accordance with an operation by a user. The power supply section 248 appropriately supplies various kinds of power for operation to the imaging device 1, the DSP circuit 243, the frame memory 244, the display section 245, the storage section 246, and the operation section 247 that are supply targets.

Next, an imaging procedure of the imaging system 4 is described.

FIG. 21 illustrates an example of a flowchart of the imaging operation of the imaging system 4. A user issues an instruction to start imaging by operating the operation section 247 (step S101). The operation section 247 then transmits an imaging instruction to the imaging device 1 (step S102). The imaging device 1 (specifically, a system control circuit) executes imaging in a predetermined imaging method upon receiving the imaging instruction (step S103).

The imaging device 1 outputs image data obtained through imaging to the DSP circuit 243. Here, the image data refers to data for all of the pixels of pixel signals generated on the basis of electric charge temporarily held in the floating diffusions FD. The DSP circuit 243 performs predetermined signal processing (e.g., a noise reduction process or the like) on the basis of the image data inputted from the imaging device 1 (step S104). The DSP circuit 243 causes the frame memory 244 to hold the image data subjected to the predetermined signal processing and the frame memory 244 causes the storage section 246 to store the image data (step S105). In this way, the imaging of the imaging system 4 is performed.

In the present application example, the imaging device (e.g., the imaging device 1) according to any of the first to third embodiments described above and the modification examples thereof is applied to the imaging system 4. This allows the imaging device 1 to be smaller or higher in definition. It is thus possible to provide the small or high-definition imaging system 4.

### 6. PRACTICAL APPLICATION EXAMPLES

### (Example of Practical Application to Mobile Body)

The technology (the present technology) according to the present disclosure is applicable to a variety of products. For example, the technology according to the present disclosure may be achieved as a device mounted on any type of mobile body such as an automobile, an electric vehicle, a hybrid electric vehicle, a motorcycle, a bicycle, a personal mobility, an airplane, a drone, a vessel, or a robot.

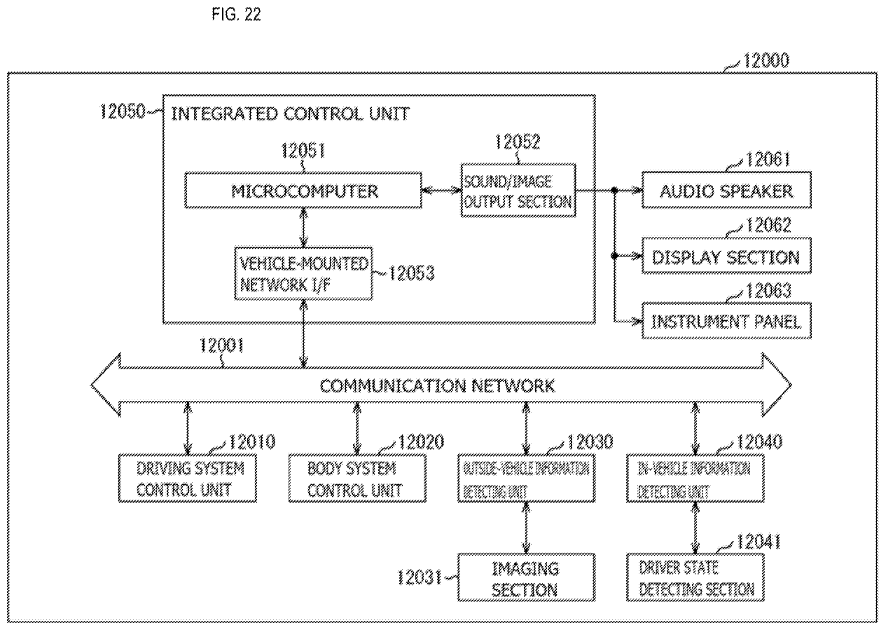

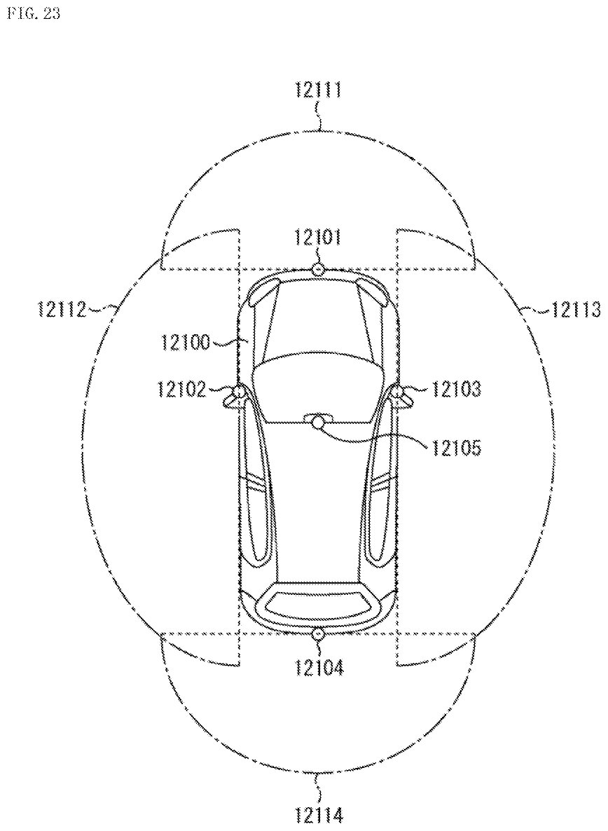

FIG. 22 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 22, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 57, an audio speaker 12061, a display section 12062, and an instrument panel 12063 are illustrated as the output device. The display section 12062 may, for example, include at least one of an on-board display and a head-up display.

FIG. 23 is a diagram depicting an example of the installation position of the imaging section 12031.

In FIG. 23, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 23 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The above has described the example of the mobile body control system to which the technology according to the present disclosure may be applied. The technology according to the present disclosure may be applied to the imaging section 12031 among the components described above. Specifically, the imaging device 1 according to any of the embodiments described above and the modification examples thereof is applicable to the imaging section 12031. The application of the technology according to the present disclosure to the imaging section 12031 makes it possible to obtain a high-definition shot image with less noise and it is thus possible to perform highly accurate control using the shot image in the mobile body control system.

### (Example of Practical Application to Endoscopic Surgery System)

The technology (the present technology) according to the present disclosure is applicable to a variety of products. For example, the technology according to the present disclosure may be applied to an endoscopic surgery system.

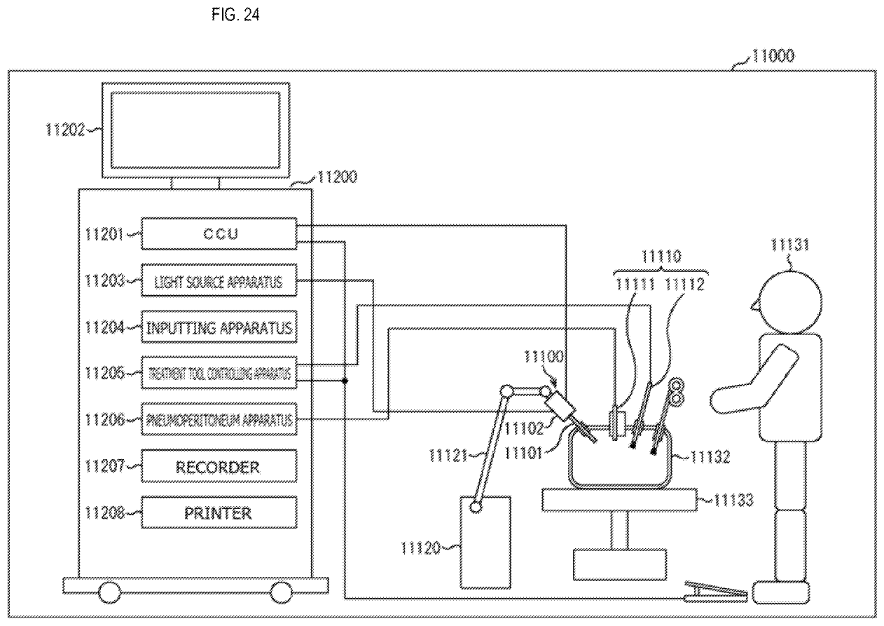

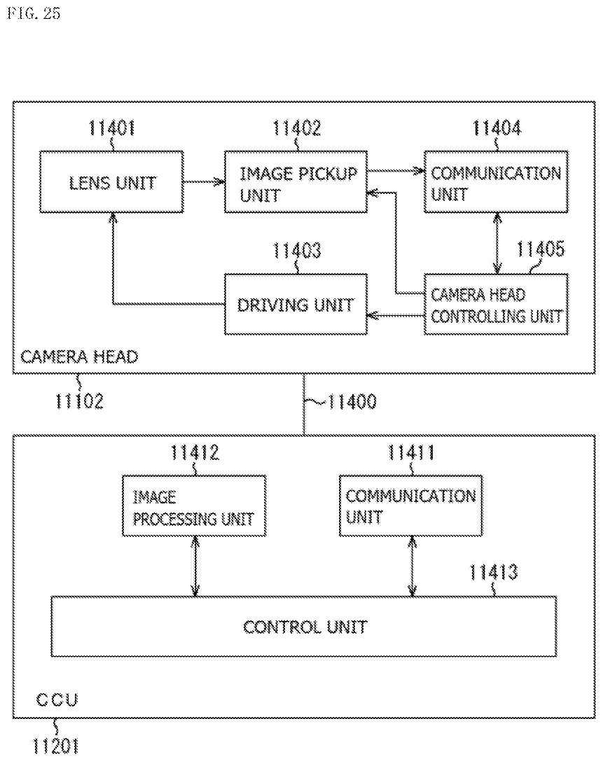

FIG. 24 is a view depicting an example of a schematic configuration of an endoscopic surgery system to which the technology according to an embodiment of the present disclosure (present technology) can be applied.

In FIG. 24, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

FIG. 25 is a block diagram depicting an example of a functional configuration of the camera head 11102 and the CCU 11201 depicted in FIG. 24.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

The above has described the example of the endoscopic surgery system to which the technology according to the present disclosure may be applied. The technology according to the present disclosure may be favorably applied to the image pickup unit 11402 provided to the camera head 11102 of the endoscope 11100 among the components described above. The application of the technology according to the present disclosure to the image pickup unit 11402 makes it possible to make the image pickup unit 11402 smaller or higher in definition and it is thus possible to provide the small or high-definition endoscope 11100.

Although the present disclosure has been described above with reference to the first to third embodiments and the modification examples 1 to 5, and the application example and the practical application examples, the present disclosure is not limited to the embodiments or the like described above. A variety of modifications are possible. For example, in any of the embodiments and the like described above, the example has been described in which the three substrates are stacked, but this is not limitative. For example, the imaging device 1B according to the modification example 2 described above in which the first substrate 100, the second substrate 200A, and the second substrate 200B are stacked may be further provided with the third substrate 300 on the second substrate 200B.

It is to be noted that the effects described herein are merely illustrative. The effects according to the present disclosure are not limited to the effects described herein. The present disclosure may have effects other than the effects described herein.

It is to be noted that the present disclosure may also have configurations as follows. According to the present technology having the following configurations, a transistor that operates in a full depletion mode is used as a transistor provided in a second substrate stacked on a first substrate including one or more sensor pixels. This makes it possible to reduce a thickness of the second substrate. It is thus possible to decrease, for example, area of a wiring line in an in-plane direction, achieving miniaturization. The wiring line electrically couples the first substrate and the second substrate.

(1)

An imaging device including:
a first substrate including one or more sensor pixels that each perform photoelectric conversion; and
a second substrate that is stacked on the first substrate and electrically coupled to the first substrate, the second substrate including a transistor that operates in a full depletion mode.
   (2)

The imaging device according to (1), in which the transistor has a three-dimensional structure.

(3)

The imaging device according to (1) or (2), in which the transistor has a Fin-FET structure in which the transistor includes a plurality of fins.

(4)

The imaging device according to (3), in which the plurality of fins is coupled to each other by a semiconductor layer having a thickness of 1 μm or less.

(5)

The imaging device according to (4), in which no ion is implanted into the semiconductor layer.

(6)

The imaging device according to any one of (3) to (5), in which the plurality of fins is independent of each other.

(7)

The imaging device according to any one of (1) to (6), in which the transistor has a gate-all-around structure.

(8)

The imaging device according to any one of (1) to (7), in which the first substrate and the second substrate are electrically coupled through a gate of the transistor or a wiring line formed in a same layer as a layer of the gate.

(9)

The imaging device according to any one of (1) to (8), in which the second substrate has a first surface provided with a gate of the transistor and a second surface opposite to the first surface and the second substrate is joined to the first substrate with the second surface interposed in between.

(10)

The imaging device according to any one of (1) to (8), in which the second substrate has a first surface provided with a gate of the transistor and a second surface opposite to the first surface and the second substrate is joined to the first substrate with the first surface interposed in between.

(11)

The imaging device according to any one of (1) to (10), in which the second substrate has a first surface provided with a gate of the transistor and a second surface opposite to the first surface and the second substrate is further provided with a multilayer wiring layer on the second surface side.

(12)

The imaging device according to (11), in which the multilayer wiring layer is provided with at least one of a power supply line, a ground line, a signal line, a resistance element, a capacitance element, an inductor element, or a memory element.

(13)

The imaging device according to (11) or (12), in which
the second substrate further includes a logic circuit block, and
a power supply line and a ground line are disposed in the multilayer wiring layer, the power supply line and the ground line being included in the logic circuit block.
   (14)

The imaging device according to any one of (1) to (13), in which two or more layers each provided with the transistor are stacked in the second substrate.

(15)

The imaging device according to any one of (1) to (14), in which
the second substrate includes a pixel circuit that outputs a pixel circuit based on electric charge outputted from the sensor pixel, and
the pixel circuit includes the transistor.
   (16)

The imaging device according to any one of (1) to (15), in which the second substrate includes an analog circuit including the transistor.

(17)

The imaging device according to any one of (1) to (16), further including a third substrate including a logic circuit.

(18)

The imaging device according to (17), in which a circuit including the transistor of the second substrate and the logic circuit of the third substrate are each provided for each of the sensor pixels.

(19)

The imaging device according to (17) or (18), in which the logic circuit includes a plurality of logic sections having different technology nodes.

(20)

The imaging device according to any one of (17) to (19), in which the logic circuit includes a memory section.

(21)

The imaging device according to any one of (17) to (20), in which the logic circuit includes a transistor that is driven by using a lower power supply voltage than a power supply voltage of the transistor.

(22)

The imaging device according to (9) or any one of (11) to (21), further including a third substrate including a logic circuit, in which
the third substrate is joined to the first surface of the second substrate by metal bonding.
   (23)

The imaging device according to any one of (10) to (21), further including a third substrate including a logic circuit, in which
the third substrate is joined to the second surface of the second substrate by metal bonding.
   (24)

An electronic apparatus including
an imaging device including
   a first substrate including one or more sensor pixels that each perform photoelectric conversion, and
   a second substrate that is stacked on the first substrate, the second substrate including a transistor that operates in a full depletion mode.

This application claims the priority on the basis of Japanese Patent Application No. 2020-174497 filed with Japan Patent Office on Oct. 16, 2020, the entire contents of which are incorporated in this application by reference.

It should be understood by those skilled in the art that various modifications, combinations, sub-combinations, and alterations may occur depending on design requirements and other factors insofar as they are within the scope of the appended claims or the equivalents thereof.

What is claimed is:

1. An imaging device, comprising:
a first substrate including one or more sensor pixels that each perform photoelectric conversion; and
a second substrate that is stacked on the first substrate and electrically coupled to the first substrate, the second substrate including a transistor that operates in a full depletion mode.

2. The imaging device according to claim 1, wherein the transistor has a three-dimensional structure.

3. The imaging device according to claim 1, wherein the transistor has a Fin-FET structure in which the transistor includes a plurality of fins.

4. The imaging device according to claim 3, wherein the plurality of fins is coupled to each other by a semiconductor layer having a thickness of 1 μm or less.

5. The imaging device according to claim 4, wherein no ion is implanted into the semiconductor layer.

6. The imaging device according to claim 3, wherein the plurality of fins is independent of each other.

7. The imaging device according to claim 1, wherein the transistor has a gate-all-around structure.

8. The imaging device according to claim 1, wherein the first substrate and the second substrate are electrically coupled through a gate of the transistor or a wiring line formed in a same layer as a layer of the gate.

9. The imaging device according to claim 1, wherein the second substrate has a first surface provided with a gate of the transistor and a second surface opposite to the first surface and the second substrate is joined to the first substrate with the second surface interposed in between.

10. The imaging device according to claim 1, wherein the second substrate has a first surface provided with a gate of the transistor and a second surface opposite to the first surface and the second substrate is joined to the first substrate with the first surface interposed in between.

11. The imaging device according to claim 1, wherein the second substrate has a first surface provided with a gate of the transistor and a second surface opposite to the first surface and the second substrate is further provided with a multilayer wiring layer on the second surface side.

12. The imaging device according to claim 11, wherein the multilayer wiring layer is provided with at least one of a power supply line, a ground line, a signal line, a resistance element, a capacitance element, an inductor element, or a memory element.

13. The imaging device according to claim 11, wherein the second substrate further includes a logic circuit block, and
a power supply line and a ground line are disposed in the multilayer wiring layer, the power supply line and the ground line being included in the logic circuit block.

14. The imaging device according to claim 1, wherein two or more layers each provided with the transistor are stacked in the second substrate.

15. The imaging device according to claim 1, wherein
the second substrate includes a pixel circuit that outputs a pixel circuit based on electric charge outputted from the sensor pixel, and
the pixel circuit includes the transistor.

16. The imaging device according to claim 1, wherein the second substrate includes an analog circuit including the transistor.

17. The imaging device according to claim 1, further comprising a third substrate including a logic circuit.

18. The imaging device according to claim 17, wherein a circuit including the transistor of the second substrate and the logic circuit of the third substrate are each provided for each of the sensor pixels.

19. The imaging device according to claim 17, wherein the logic circuit includes a plurality of logic sections having different technology nodes.

20. The imaging device according to claim 17, wherein the logic circuit includes a memory section.

21. The imaging device according to claim 17, wherein the logic circuit includes a transistor that is driven by using a lower power supply voltage than a power supply voltage of the transistor.

22. The imaging device according to claim 9, further comprising a third substrate including a logic circuit, wherein
the third substrate is joined to the first surface of the second substrate by metal bonding.

23. The imaging device according to claim 10, further comprising a third substrate including a logic circuit, wherein
the third substrate is joined to the second surface of the second substrate by metal bonding.

24. An electronic apparatus, comprising an imaging device, including:
a first substrate including one or more sensor pixels that each perform photoelectric conversion; and
a second substrate that is stacked on the first substrate, the second substrate including a transistor that operates in a full depletion mode.
